(19) United States
(12) Patent Application Publication
(10) Pub. No.: US 2026/0371564 A1
(43) Pub. Date: Nov. 19, 2026

(54) SEMICONDUCTOR DEVICE INCLUDING ACTIVE PATTERN

(71) Applicant: Samsung Electronics Co., Ltd., Suwon-si (KR)

(72) Inventors: Juho Lee, Suwon-si (KR); Sungjin Kim, Suwon-si (KR); Pilsang Yun, Suwon-si (KR); Minhwan Lee, Suwon-si (KR); Wonsok Lee, Suwon-si (KR); Minhee Cho, Suwon-si (KR); Sungduk Hong, Suwon-si (KR)

(21) Appl. No.: 19/648,917

(22) Filed: Apr. 15, 2026

(30) Foreign Application Priority Data
May 16, 2025 (KR) 10-2025-0063726

(51) Int. Cl. H10B 12/00; H10B 80/00; H10D 30/67; H10D 80/30; H10W 20/41; H10W 90/00

(52) U.S. Cl. CPC H10B 12/33; H10B 12/482; H10D 30/6728; H10D 30/6736; H10D 30/6757; H10W 20/435; H10B 12/05; H10B 80/00; H10D 80/30; H10W 90/792

(57) ABSTRACT

A semiconductor device includes active patterns spaced apart from each other in a first horizontal direction, a gate electrode surrounding at least a portion of the active patterns, the gate electrode extending in the first horizontal direction, and a gate dielectric layer disposed between the active patterns and the gate electrode, the gate dielectric layer partially covering side surfaces of the active patterns. The active patterns include first active patterns overlapping first recesses of the gate electrode in a second horizontal direction, and second active patterns overlapping second recesses of the gate electrode in the second horizontal direction. The first active patterns and the second active patterns are alternately disposed in the first horizontal direction.

### CROSS-REFERENCE TO RELATED APPLICATION

This application claims benefit of priority to Korean Patent Application No. 10-2025-0063726 filed on May 16, 2025, in the Korean Intellectual Property Office, the disclosure of which is incorporated herein by reference in its entirety.

### BACKGROUND

As demand for the implementation of high performance, high speed, and/or multifunctionalization of semiconductor devices increases, a degree of integration of semiconductor devices has been increasing. Manufacturing of semiconductor devices having a fine pattern corresponding to the trend for a high degree of integration of semiconductor devices has led some techniques that implement patterns having a fine width or a fine separation distance.

### SUMMARY

The present disclosure relates to a semiconductor device including an active pattern.

An aspect of the present disclosure is to provide a semiconductor device including active patterns disposed in a honeycomb structure.

According to an aspect of the present disclosure, there is provided a semiconductor device including active patterns extending in a vertical direction, the active patterns spaced apart from each other in a first horizontal direction, landing pads and bit lines in contact with the active patterns, the landing pads and the bit lines spaced apart from each other in the vertical direction with the active patterns interposed therebetween, the bit lines extending in a second horizontal direction, intersecting the first horizontal direction, a gate electrode surrounding at least a portion of the active patterns, the gate electrode extending in the first horizontal direction, and a gate dielectric layer disposed between the active patterns and the gate electrode, the gate dielectric layer partially covering side surfaces of the active patterns. The gate electrode may include a first side surface including first recesses, and a second side surface opposite to the first side surface, the second side surface including second recesses. The active patterns may include first active patterns overlapping the first recesses in the second horizontal direction, and second active patterns overlapping the second recesses in the second horizontal direction. The first active patterns and the second active patterns may be alternately disposed in the first horizontal direction.

According to another aspect of the present disclosure, there is provided a semiconductor device including active patterns extending in a vertical direction, the active patterns spaced apart from each other in a first horizontal direction, landing pads and bit lines in contact with the active patterns, the landing pads and the bit lines spaced apart from each other in the vertical direction with the active patterns interposed therebetween, the bit lines extending in a second horizontal direction, intersecting the first horizontal direction, a gate electrode surrounding at least a portion of the active patterns, the gate electrode extending in the first horizontal direction, the gate electrode including a first side surface including first recesses, and a second side surface opposite to the first side surface, the second side surface including second recesses, a first insulating structure in contact with the first side surface of the gate electrode, the first insulating structure extending in the first horizontal direction, and a second insulating structure in contact with the second side surface of the gate electrode, the second insulating structure extending in the first horizontal direction. The active patterns may include first active patterns overlapping the first recesses in the second horizontal direction, and second active patterns overlapping the second recesses in the second horizontal direction. The first active patterns may be in contact with the first insulating structure. The second active patterns may be in contact with the second insulating structure. The first active patterns and the second active patterns may be alternately disposed in the first horizontal direction.

According to another aspect of the present disclosure, there is provided a semiconductor device including a cell array structure, and a peripheral circuit structure bonded to the cell array structure. The cell array structure may include active patterns extending in a vertical direction, the active patterns spaced apart from each other in a first horizontal direction, landing pads and bit lines in contact with the active patterns, the landing pads and the bit lines spaced apart from each other in the vertical direction with the active patterns interposed therebetween, the bit lines extending in a second horizontal direction, intersecting the first horizontal direction, a gate electrode surrounding at least a portion of the active patterns, the gate electrode extending in the first horizontal direction, the gate electrode including a first side surface including first recesses, and a second side surface opposite to the first side surface, the second side surface including second recesses, and an information storage structure on the landing pads. The peripheral circuit structure may include a circuit element disposed on a substrate, the circuit element electrically connected to the bit line. The active patterns may include first active patterns overlapping the first recesses in the second horizontal direction, and second active patterns overlapping the second recesses in the second horizontal direction. The first active patterns and the second active patterns may be alternately disposed in the first horizontal direction.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a plan view of a semiconductor device according to some implementations;

FIG. 2 is a vertical cross-sectional view of the semiconductor device illustrated in FIG. 1, taken along line I-I′;

FIG. 3 is a partially enlarged view of the semiconductor device illustrated in FIG. 1;

FIG. 4 is a partially enlarged view of the semiconductor device illustrated in FIG. 2;

FIG. 5 illustrates an arrangement structure of active patterns and landing pads;

FIGS. 6, 7, 8, and 9 are vertical cross-sectional views of a semiconductor device according to some implementations;

FIG. 10 is a flowchart of a method of manufacturing a semiconductor device according to some implementations;

FIGS. 11A, 11B, 12A, 12B, 13A, 13B, 14A, 14B, 15, 16A, 16B, 17A, 17B are plan views and vertical cross-sectional views of sequential processes in a method of manufacturing a semiconductor device according to some implementations;

FIG. 18 is a plan view of a semiconductor device according to some implementations;

FIG. 19 is a vertical cross-sectional view of the semiconductor device illustrated in FIG. 18, taken along line I-I′;

FIG. 20 is a partially enlarged view of the semiconductor device illustrated in FIG. 18;

FIGS. 21 and 22 are plan views of semiconductor devices according to some implementations;

FIG. 23 is a vertical cross-sectional view of a semiconductor device according to some implementations;

FIG. 24 is a partially enlarged view of the semiconductor device illustrated in FIG. 23;

FIG. 25 is a flowchart of a method of manufacturing a semiconductor device according to some implementations; and

FIGS. 26A, 26B, 27A, 27B are plan views and vertical cross-sectional views of sequential processes in a method of manufacturing a semiconductor device according to some implementations.

### DETAILED DESCRIPTION

Hereinafter, example implementations of the present disclosure will be described with reference to the accompanying drawings as follows.

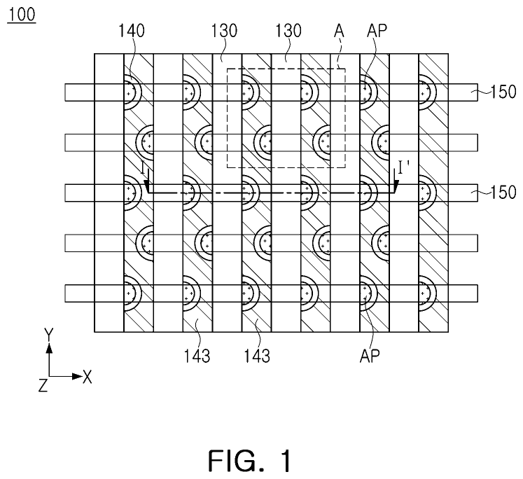

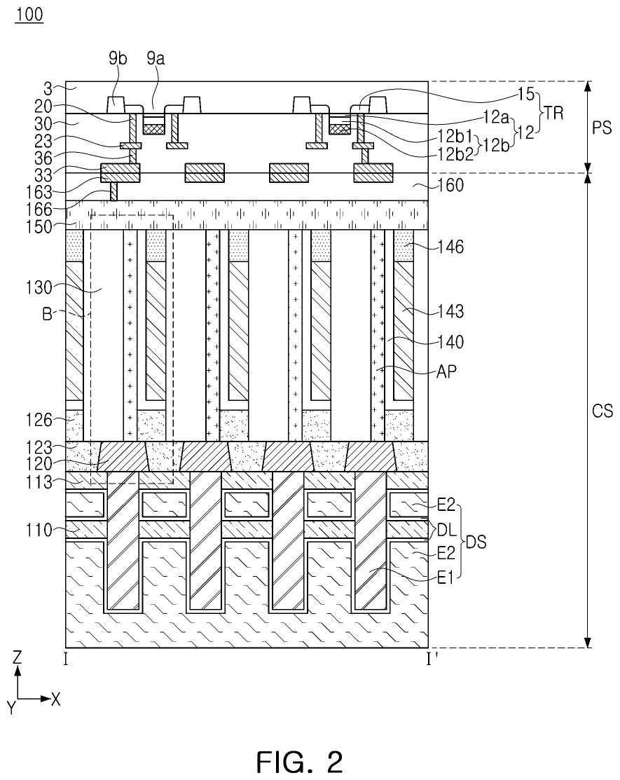

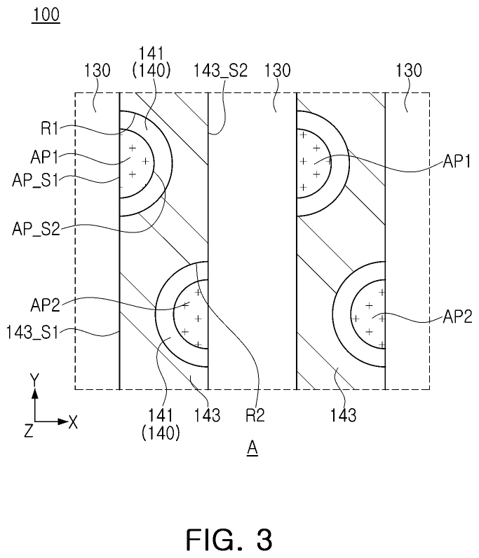

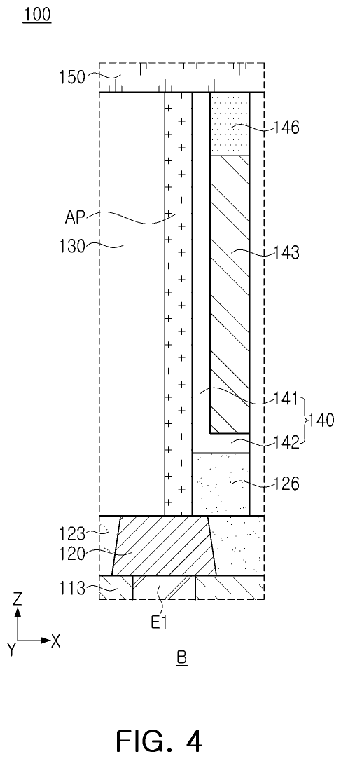

FIG. 1 is a plan view of a semiconductor device according to some implementations. FIG. 2 is a vertical cross-sectional view of the semiconductor device illustrated in FIG. 1, taken along line I-I′. FIG. 3 is a partially enlarged view of the semiconductor device illustrated in FIG. 1. FIG. 3 may correspond to region “A” of FIG. 1. FIG. 4 is a partially enlarged view of the semiconductor device illustrated in FIG. 2. FIG. 4 may correspond to region “B” of FIG. 2

Referring to FIGS. 1 to 4, a semiconductor device 100 according to some implementations of the present disclosure may include a cell array structure CS and a peripheral circuit structure PS on the cell array structure CS. The cell array structure CS may include an information storage structure DS, a landing pad 120, an active pattern AP, and a bit lines 150.

The information storage structure DS may include first electrodes E1, second electrodes E2 on the first electrodes E1, and a dielectric layer DL between the first electrodes E1 and the second electrodes E2. The first electrodes E1 and the second electrodes E2 may also be referred to as lower electrodes and upper electrodes, respectively.

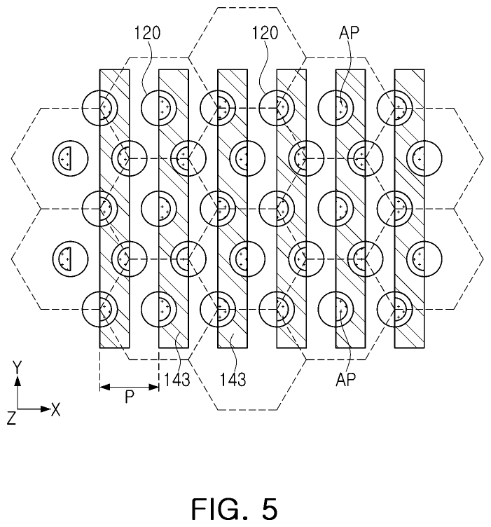

The first electrodes E1 may extend in a vertical direction, and may be spaced apart from each other in a horizontal direction. As will be described below with reference to FIG. 5, the first electrodes E1 may be disposed in a honeycomb structure. For example, the first electrodes E1 may be disposed at respective vertices of a hexagon and at the center of the hexagon. The first electrodes E1 may include at least one of TiN, TiAlN, TiSiN, TaN, TaAlN, TaSiN, or WN.

The cell array structure CS may further include a lower support layer 110 and an upper support layer 113 disposed between the first electrodes E1. The lower support layer 110 and the upper support layer 113 may be in contact with side surfaces of the first electrodes E1, and may support the first electrodes E1. The upper support layer 113 may be disposed on the lower support layer 110. For example, an upper surface of the upper support layer 113 may be coplanar with upper surfaces of the first electrodes E1. In some implementations, the lower support layer 110 may be omitted. The lower support layer 110 and the upper support layer 113 may include an insulating material, for example, silicon oxide, silicon nitride, silicon oxynitride, or combinations thereof. In some implementations, the lower support layer 110 and the upper support layer 113 may include silicon nitride.

The dielectric layer DL may cover the first electrodes E1, the lower support layer 110, and the upper support layer 113. For example, the dielectric layer DL may be conformally formed along surfaces of the first electrodes E1, the lower support layer 110, and the upper support layer 113. The dielectric layer DL may cover an upper surface and a lower surface of the lower support layer 110 and may cover a lower surface of the upper support layer 113.

In some implementations, the information storage structure DS may be a capacitor storing information in DRAM. For example, the dielectric layer DL of the information storage structure DS may be a capacitor dielectric layer of the DRAM, and may include a high-κ dielectric, silicon oxide, silicon nitride, silicon oxynitride, or combinations thereof.

In another example, the information storage structure DS may be a structure storing information of a memory different from the DRAM. For example, the information storage structure DS may be a capacitor of a ferroelectric memory (FeRAM). In this case, the dielectric layer DL may be a ferroelectric layer capable of recording data using a polarization state. In another example, the dielectric layer DL may include a lower dielectric layer and a ferroelectric layer on the lower dielectric layer. Here, the lower dielectric layer may include at least one of silicon oxide, silicon oxynitride, silicon nitride, and a high-κ dielectric.

In some implementations, when the dielectric layers DL include an information storage layer, the information storage structure DS may be omitted.

The second electrode E2 may cover the dielectric layer DL, and may fill a space between the first electrodes E1. The second electrode E2 may not cover the upper surfaces of the first electrodes E1, and an upper surface of the second electrode E2 may be positioned at a level, lower than that of the upper surfaces of the first electrodes E1. The second electrode E2 may include a semiconductor material and, for example, may include silicon germanium (SiGe) including impurities.

The landing pad 120 may be disposed on the information storage structure DS. For example, the landing pads 120 may be in contact with the upper surfaces of the corresponding first electrodes E1, respectively, and may be electrically connected to the upper surfaces of the corresponding first electrodes E1, respectively. In some implementations, the landing pads 120 may be disposed in a honeycomb structure. In some implementations, a horizontal width of a lower surface of the landing pad 120 may be greater than a horizontal width of the upper surface of the first electrode E1. In some implementations, a horizontal width of the landing pad 120 may decrease upwardly. For example, the horizontal width of the landing pad 120 may decrease as a distance from the active pattern AP decreases.

The landing pad 120 may include a metal nitride, a metal, or a combination thereof. The metal nitride may include at least one of TiN, TaN, WN, TiSiN, TaSiN, or RuTiN, and the metal layer may include a metal material such as W or Mo.

The cell array structure CS may further include a pad insulating layer 123 covering side surfaces of the landing pads 120. A lower surface of the pad insulating layer 123 may be in contact with an upper surface of the upper support layer 113, and an upper surface of the pad insulating layer 123 may be coplanar with upper surfaces of the landing pads 120. The pad insulating layer 123 may include silicon oxide, silicon nitride, silicon oxynitride, a low-κ dielectric, or combinations thereof, and may include, for example, silicon nitride.

The cell array structure CS may further include an insulating pattern 126 and an insulating structure 130, disposed on the landing pad 120. The upper surface of the landing pad 120 may be in contact with the insulating pattern 126 and the insulating structure 130. The insulating patterns 126 and the insulating structures 130 may extend in a Y-direction (also referred to as “the second horizontal direction), and may be spaced apart from each other in an X-direction (also referred to as “the first horizontal direction”). For example, the insulating patterns 126 and the insulating structures 130 may be alternately disposed in the X-direction. Lower surfaces of the insulating patterns 126 may be coplanar with lower surfaces of the insulating structures 130. Upper surfaces of the insulating patterns 126 may be positioned at a level, lower than that of upper surfaces of the insulating structures 130.

The insulating pattern 126 and the insulating structure 130 may include silicon oxide, silicon nitride, silicon oxynitride, or combinations thereof. For example, the insulating pattern 126 may include silicon nitride, and the insulating structure 130 may include silicon oxide. Each of the insulating pattern 126 and the insulating structure 130 may be formed of a single layer or a plurality of layers.

The cell array structure CS may further include gate electrodes 143 disposed on the active patterns AP, gate dielectric layers 140 disposed between the gate electrodes 143 and the active patterns AP, and gate capping layers 146 on the gate electrodes 143.

The active pattern AP may be in contact with the upper surface of the landing pad 120, and may extend in the vertical direction (Z-direction). The active patterns AP may be spaced apart from each other in the X-direction and the Y-direction. Lower surfaces and upper surfaces of the active patterns AP may be coplanar with lower surfaces and upper surfaces of the insulating structures 130, respectively.

A side surface of the active pattern AP may include a first portion AP_S1 and a second portion AP_S2. In some implementations, the gate dielectric layer 140 may at least partially cover the side surface of the active pattern AP. For example, the first portion AP_S1 of the side surface of the active pattern AP may be in contact with the insulating structure 130, and may not be in contact with the gate dielectric layer 140. In some implementations, in a plan view, the first portion AP_S1 of the side surface of the active pattern AP may be coplanar with the side surface of the insulating structure 130. The second portion AP_S2 of the side surface of the active pattern AP may be in contact with the gate dielectric layer 140. In some implementations, in a plan view, the active pattern AP may have a semicircular shape, but the present disclosure is not limited thereto. In some implementations, the active pattern AP may have a triangular shape, a rectangular shape, or an elliptical shape.

In some implementations, the active pattern AP may include an oxide semiconductor material that may be used as a channel region of a transistor. However, the active pattern AP is not limited to the oxide semiconductor material, and may be formed of another semiconductor material that may be used as a channel region of a transistor.

The oxide semiconductor material may be indium gallium zinc oxide (IGZO). However, the implementations are not limited thereto. For example, the oxide semiconductor material may include at least one of indium tungsten oxide (IWO), indium tin gallium oxide (ITGO), indium aluminum zinc oxide (IAGO), indium gallium oxide (IGO), indium tin zinc oxide (ITZO), zinc tin oxide (ZTO), indium zinc oxide (IZO), ZnO, indium gallium silicon oxide (IGSO), indium oxide (InO), tin oxide (SnO), titanium oxide (TiO), zinc oxide (ZnON), manganese zinc oxide (MgZnO), indium zinc oxide (InZnO), indium gallium zinc oxide (InGaZnO), zirconium indium zinc oxide (ZrInZnO), hafnium indium zinc oxide (HfInZnO), tin indium zinc oxide (SnInZnO), aluminum tin indium zinc oxide (AlSnInZnO), silicon indium zinc oxide (SiInZnO), zinc tin oxide (ZnSnO), aluminum zinc tin oxide (AlZnSnO), gallium zinc tin oxide (GaZnSnO), zirconium zinc tin oxide (ZrZnSnO), and indium gallium silicon oxide (InGaSiO).

In some implementations, the active pattern AP may include a two-dimensional (2D) material layer that may be used as a channel region of a transistor.

The 2D material layer may include at least one of a transition metal dichalcogenide (TMD) material layer, a black phosphorous material layer, and a hexagonal boron-nitride (hBN) material layer, which may have semiconductor properties. For example, the 2D material layer may include at least one of BiOSe, CrI, WSe₂, MoS₂, TaS, WS, SnSe, ReS, β-SnTe, MnO, AsS, P (black), InSe, h-BN, GaSe, GaN, SrTiO, MXene, and a Janus 2D material, which may form a 2D material.

In some implementations, the active pattern AP may be formed of a semiconductor material such as silicon. For example, the active pattern AP may be formed of single crystalline silicon or polysilicon.

In a plan view, the gate electrodes 143 may intersect with the bit lines 150. For example, the gate electrodes 143 may extend in the Y-direction along side surfaces of insulating structures 130, and may be spaced apart from each other in the X-direction. The gate electrodes 143 may be alternately disposed with the insulating structures 130 in the X-direction. The gate electrode 143 may surround at least a portion of the active pattern AP, and may overlap the active pattern AP in the X-direction and the Y-direction. An upper surface of the gate electrode 143 may be positioned at a level, lower than that of an upper surface of the active pattern AP. A lower surface of the gate electrode 143 may be positioned at a level, higher than that of a lower surface of the active pattern AP. At least one of the gate electrodes 143 may be a cell gate electrode or a word line.

The gate electrode 143 may include a first side surface 143_S1 and a second side surface 143_S2 opposite to the first side surface 143_S1. The first side surface 143_S1 of the gate electrode 143 may be spaced apart from the second side surface 143_S2 of the gate electrode 143 in the X-direction. In some implementations, the first side surface 143_S1 of the gate electrode 143 may include first recesses R1 spaced apart from each other in the Y-direction, and the second side surface 143_S2 of the gate electrode 143 may include second recesses R2 spaced apart from each other in the Y-direction. The first recesses R1 and the second recesses R2 may not overlap each other in the X-direction. For example, the first recesses R1 and the second recesses R2 may be alternately disposed in the Y-direction.

The active patterns AP may overlap the first recesses R1 and the second recesses R2 in the X-direction. The active pattern AP overlapping the first recesses R1 in the X-direction may be referred to as a first active pattern AP1, and the active pattern AP overlapping the second recesses R2 in the X-direction may be referred to as a second active pattern AP2. The first active patterns AP1 and the second active patterns AP2 may be disposed to be offset from each other in the X-direction, and may be alternately disposed in the Y-direction. In some implementations, the first portions AP_S1 of the side surfaces of the first active patterns AP1 may be coplanar with the first side surface 143_S1 of the gate electrode 143. The first portions AP_S1 of the side surfaces of the second active patterns AP2 may be coplanar with the second side surface 143_S2 of the gate electrode 143. The first active patterns AP1 and the second active patterns AP2 may overlap the gate electrode 143 in the Y-direction.

The gate dielectric layer 140 may be disposed on the insulating pattern 126, and may be disposed between the gate electrode 143 and the active patterns AP. In some implementations, the gate dielectric layer 140 may include vertical portions 141 and a horizontal portion 142. The vertical portions 141 may extend in the vertical direction between the gate electrode 143 and the active patterns AP. For example, the vertical portions 141 may be in contact with the first recesses R1 and the second recesses R2 of the gate electrode 143. Each of the vertical portions 141 may be in contact with the first recess R1, and may extend between the gate electrode 143 and the first active pattern AP1, or may be in contact with the second recess R2, and may extend between the gate electrode 143 and the second active pattern AP2. In some implementations, in a plan view, the vertical portions 141 may have a U-shape or an arc shape. In some implementations, each of the vertical portions 141 may be coplanar with the first active pattern AP1 and the first side surface 143_S1 of the gate electrode 143, or may be coplanar with the second active pattern AP2 and the second side surface 143_S2 of the gate electrode 143. Upper surfaces of the vertical portions 141 may be coplanar with upper surfaces of the active patterns AP. The vertical portions 141 in contact with the first recesses R1 and the second recesses R2 may be referred to as first vertical portions and second vertical portions, respectively.

The horizontal portion 142 may extend in the horizontal direction between the insulating pattern 126 and the gate electrode 143. For example, the horizontal portion 142 may extend in the Y-direction along a lower surface of the gate electrode 143 between the insulating structures 130 adjacent to each other in the X-direction, and may be connected to a plurality of vertical portions 141. The horizontal portion 142 may be disposed at a level, higher than that of a lower surface of the active pattern AP.

As used herein, a vertical portion 141 in contact with the first active pattern AP1 and the first recesses R1 of the gate electrode 143 may be referred to as a “first vertical portion,” and a vertical portion 141 in contact with the second active patterns AP2 and the second recesses R2 of the gate electrode 143 may be referred to as a “second vertical portion.” In some implementations, the first vertical portion may be coplanar with the first side surface 143_S1 of the gate electrode 143, and the second vertical portion may be coplanar with the second side surface 143_S2 of the gate electrode 143.

In an example, each of the gate dielectric layers 140 may be a tunnel dielectric layer, not including an information storage layer. For example, each of the gate dielectric layers 140 may include at least one of silicon oxide and a high-κ dielectric. The high-κ dielectric may include metal oxide or metal oxynitride. For example, the high-κ dielectric may be formed of HfO₂, HfSiO, HfSiON, HfTaO, HfTiO, HfZrO, ZrO₂, Al₂O₃, or combinations thereof, but the present disclosure is not limited thereto. Each of the gate dielectric layers 140 may be formed of a single layer or multiple layers, formed of the above-described materials.

In another example, each of the gate dielectric layers 152 may include an information storage layer and a dielectric layer. For example, each of the gate dielectric layers 152 may have polarization properties depending on an electric field, and may include a ferroelectric layer that may have remnant polarization caused by a dipole even in the absence of an external electric field. Data may be recorded using such a polarization state in the ferroelectric layer. Accordingly, each of the gate dielectric layers 152 may include a ferroelectric layer, which may be referred to as an information storage layer. The ferroelectric layer, which may be the information storage layer, may include an Hf-based compound, a Zr-based compound, and/or an Hf—Zr-based compound. For example, the Hf-based compound may be a HfO-based ferroelectric material, the Zr-based compound may include a ZrO-based ferroelectric material, and the Hf—Zr-based compound may include a hafnium zirconium oxide (HZO)-based ferroelectric material. The ferroelectric layer, which may be the information storage layer, may include a ferroelectric material doped with an impurity, for example, at least one of C, Si, Mg, Al, Y, N, Ge, Sn, Gd, La, Sc, and Sr. For example, the ferroelectric layer, which may be the information storage layer, may be a material obtained by doping at least one of HfO₂, ZrO₂, and HZrO with at least one of C, Si, Mg, Al, Y, N, Ge, Sn, Gd, La, Sc, and Sr.

In the gate dielectric layers 140, the information storage layer is not limited to the above-described material types, and may include a material capable of storing information.

The gate capping layer 146 may cover an upper surface of the gate electrode 143. The gate capping layer 146 may extend in the Y-direction along the upper surface of the gate electrode 143, between the insulating structures 130 adjacent to each other in the X-direction. An upper surface of the gate capping layer 146 may be coplanar with upper surfaces of the active pattern AP and the insulating structures 130. A side surface of the gate capping layer 146 may be in contact with the insulating structure 130 and the gate dielectric layer 140.

The gate capping layer 146 may include silicon oxide, silicon nitride, silicon oxynitride, or combinations thereof. The gate capping layer 146 may be formed of a single layer or a plurality of layers.

The bit line 150 may be disposed on the active pattern AP, and may intersect the gate electrode 143. The bit lines 150 may extend in the X-direction, and may be spaced apart from each other in the Y-direction. The bit line 150 may be electrically connected to the landing pad 120 through the active pattern AP. The bit line 150 may include a metal layer and a barrier layer covering a side surface and a lower surface of the metal layer. The barrier layer may include at least one of TiN, TaN, WN, TiSiN, TaSiN, or RuTiN, and the metal layer may include a metal material such as W or Mo.

The cell array structure CS may further include a bit line insulating layer disposed between the bit lines 150. The bit line insulating layer may be disposed at a level, the same as that of the bit lines 150, and may electrically insulate the bit lines 150 from each other. The bit line insulating layer may include silicon oxide, silicon nitride, silicon oxynitride, or combinations thereof.

In some implementations, the cell array structure CS may further include shielding patterns extending in the X-direction, the shielding patterns spaced apart from each other in the Y-direction. The shielding patterns may be alternately disposed with the bit lines 150 in the Y-direction. The shielding patterns may reduce capacitance between the bit lines 150.

The shielding pattern may include doped polysilicon, a metal, a conductive metal nitride, a metal-semiconductor compound, a conductive metal oxide, graphene, carbon nanotubes, or combinations thereof.

The cell array structure CS may further include a cell insulating layer 160, a first bonding pad 163, and a first contact 166, disposed on the bit line 150. The first bonding pads 163 may be disposed on the bit line 150, and may be electrically connected to corresponding first contacts 166. The cell insulating layer 160 may cover the first bonding pad 163 and the first contact 166. For example, an upper surface of the first bonding pad 163 may be coplanar with an upper surface of the cell insulating layer 160. The bit line 150 may be electrically connected to at least one of the first bonding pads 163. A wiring layer, electrically connecting the first bonding pads 163 and the bit line 150 to each other, may further be disposed in the cell insulating layer 160.

The information storage structure DS, the landing pad 120, the active pattern AP, the gate dielectric layer 140, the gate electrode 143, and the bit line 150 may be included in a memory cell. The active pattern AP, the gate dielectric layer 140, and the gate electrode 143 may be included in a memory cell transistor of the memory cell.

The peripheral circuit structure PS may be disposed on the cell array structure CS. The peripheral circuit structure PS may include a substrate 3, a circuit element TR, a peripheral plug 20, a peripheral wiring 23, a peripheral insulating layer 30, a second bonding pad 33, and a second contact 36.

The substrate 3 may include a semiconductor material, for example, a group IV semiconductor, a group III-V compound semiconductor, or a group II-VI compound semiconductor. For example, the group IV semiconductor may include silicon, germanium, or silicon-germanium. The substrate 3 may be a silicon substrate, a silicon-on-insulator (SOI) substrate, a germanium substrate, a germanium-on-insulator (GOI) substrate, a silicon-germanium substrate, or a substrate including an epitaxial layer.

The circuit element TR may include a word line driver, a sense amplifier, row and column decoders, and control circuits. The circuit element TR may include a peripheral transistor. For example, the peripheral transistor may include a gate structure 12 disposed on a peripheral active region 9a defined by an element isolation region 9b in the substrate 3, and peripheral source/drain regions 15 disposed in the peripheral active region 9a on both sides of the gate structure 12.

The gate structure 12 may include a peripheral gate electrode 12b and a peripheral gate dielectric layer 12a between the peripheral gate electrode 12b and the peripheral active region 9a. The peripheral gate electrode 12b may include at least two conductive layers, for example, a first conductive layer 12b1 and a second conductive layer 12b2 below the first conductive layer 12b1.

The peripheral plug 20 may be connected to the peripheral source/drain region 15, and may extend vertically, and the peripheral wiring 23 may be disposed below the peripheral plug 20. The peripheral wiring 23 may be electrically connected to the circuit element TR through the peripheral plug 20.

The second contact 36 may be connected to the peripheral wiring 23, and may extend vertically, and the second bonding pad 33 may be disposed below the peripheral wiring 23. The second bonding pad 33 may be electrically connected to the peripheral wiring 23 through the second contact 36.

The peripheral insulating layer 30 may cover the peripheral gate electrode 12b, the peripheral plug 20, the peripheral wiring 23, the second bonding pad 33, and the second contact 36. A lower surface of the peripheral insulating layer 30 may be coplanar with a lower surface of the second bonding pad 33. The peripheral wiring 23 may be electrically connected to at least one of the second bonding pads 33. In some implementations, a wiring layer, electrically connecting the second bonding pads 33 and the peripheral wiring 23 to each other, may further be disposed in the peripheral insulating layer 30.

In some implementations, the peripheral plug 20, the peripheral wiring 23, and the second contact 36 may include a metal layer and a barrier layer covering a side surface and a lower surface of the metal layer. The barrier layer may include at least one of TiN, TaN, WN, TiSiN, TaSiN, or RuTiN, and the metal layer may include a metal material such as W or Mo.

The peripheral circuit structure PS may be bonded on the cell array structure CS, and may be electrically connected to the cell array structure CS. For example, the cell insulating layer 160 and the first bonding pad 163 of the cell array structure CS may be bonded to the peripheral insulating layer 30 and the second bonding pad 33 of the peripheral circuit structure PS, respectively.

The first bonding pad 163 and the second bonding pad 33 may include a conductive material such as copper (Cu), and the cell insulating layer 160 and the peripheral insulating layer 30 may include an insulating material such as silicon oxide.

FIG. 5 illustrates an arrangement structure of active patterns and landing pads.

Referring to FIG. 5, as described above, the landing pads 120 may be disposed in a honeycomb structure in which the landing pads 120 are disposed at respective vertices and at a center of a hexagon. The active patterns AP may be disposed on the landing pads 120, such that the active patterns AP may also be disposed in a honeycomb structure. Accordingly, as compared to a case in which the active patterns AP are disposed in a lattice structure, the active patterns AP may be disposed more densely, such that the semiconductor device 100 having a smaller size may be implemented, and a degree of integration of the semiconductor device 100 may be improved.

For example, the gate electrodes 143 may be disposed at a constant pitch P in an X-direction. The pitch P may be 2.0F. Here, F may indicate a minimum lithographic feature size. As described above, the memory cells may include the active patterns AP and the landing pads 120. That is, one memory cell may be disposed for each active pattern AP or each landing pad 120. Three adjacent hexagons may be disposed with one memory cell interposed therebetween, such that ⅓ of the memory cell may be disposed at each vertex of a hexagon, and one memory cell may be disposed at the center of the hexagon. That is, an area of one illustrated hexagon may correspond to a sum of areas of three memory cells. In this case, an area of a unit memory cell may be 2√3F² (about 3.46F²).

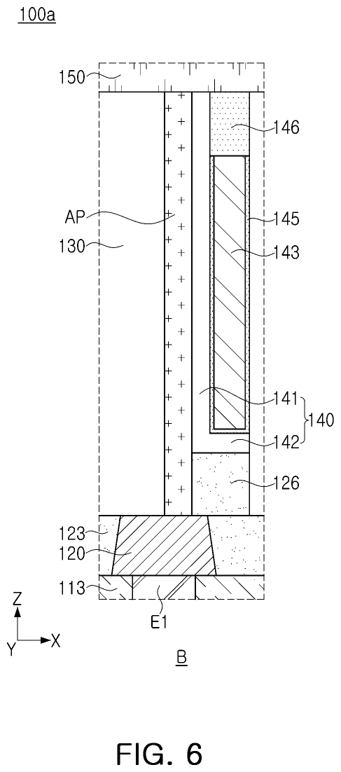

FIGS. 6 to 9 are vertical cross-sectional views of a semiconductor device according to some implementations.

Referring to FIG. 6, a semiconductor device 100a may further include a liner layer 145 covering a gate electrode 143. The liner layer 145 may cover a lower surface and side surfaces of the gate electrode 143. For example, the liner layer 145 may extend between the gate electrode 143 and a gate dielectric layer 140 and between the gate electrode 143 and an insulating structure 130. In a cross-sectional view, the liner layer 145 may have a U-shape. Due to the liner layer 145 covering the gate electrode 143, oxidation of the gate electrode 143 may be prevented.

The liner layer 145 may include silicon oxide, silicon nitride, silicon oxynitride, or combinations thereof. For example, the liner layer 145 may include silicon nitride.

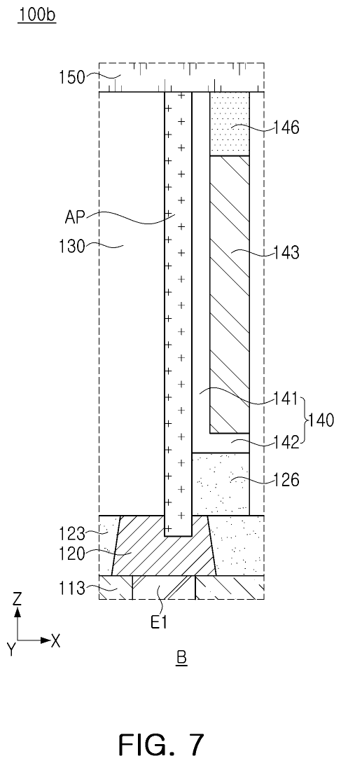

Referring to FIG. 7, a semiconductor device 100b may include an active pattern AP on a landing pad 120. In some implementations, a portion of the active pattern AP may partially pass through the landing pad 120. For example, a lower surface of the active pattern AP may be positioned at a level, lower than that of an upper surface of the landing pad 120 in contact with the insulating structure 130 and the insulating pattern 126. A side surface of a lower portion of the active pattern AP may be in contact with the landing pad 120.

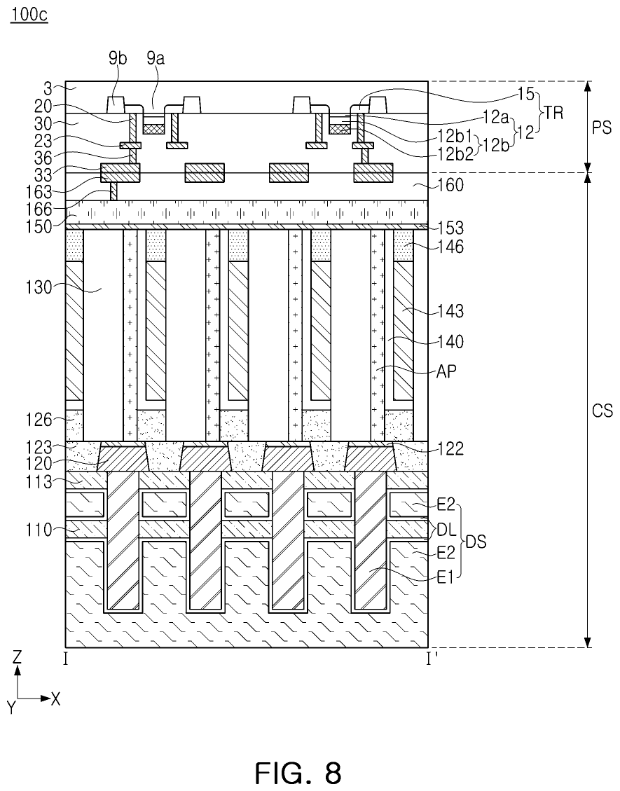

Referring to FIG. 8, a semiconductor device 100c may further include a first conductive layer 122 disposed between a landing pad 120 and an active pattern AP. For example, the first conductive layer 122 may cover an upper surface of the landing pad 120, and may be in contact with lower surfaces of the active pattern AP and an insulating structure 130. The first conductive layers 122 may be spaced apart from each other in an X-direction and a Y-direction. The first conductive layers 122 may be disposed on the landing pad 120, and thus may be disposed in a honeycomb structure.

In some implementations, the semiconductor device 100c may further include a second conductive layer 153 disposed between the active pattern AP and a bit line 150. For example, the second conductive layer 153 may cover a lower surface of the bit line 150, and may be in contact with upper surfaces of the insulating structure 130, a gate dielectric layer 140, a gate capping layer 146, and the active pattern AP. The second conductive layers 153 may extend in the X-direction, and may be spaced apart from each other in the Y-direction.

The first conductive layer 122 and the second conductive layer 153 may include an oxide semiconductor material. The oxide semiconductor material may be indium gallium zinc oxide (IGZO). However, the implementations are not limited thereto. For example, the oxide semiconductor material may include at least one of indium tungsten oxide (IWO), indium tin gallium oxide (ITGO), indium aluminum zinc oxide (IAZO), indium gallium oxide (IGO), indium tin zinc oxide (ITZO), zinc tin oxide (ZTO), indium zinc oxide (IZO), ZnO, indium gallium silicon oxide (IGSO), indium oxide (InO), tin oxide (SnO), titanium oxide (TiO), zinc oxide (ZnON), manganese zinc oxide (MgZnO), indium zinc oxide (InZnO), indium gallium zinc oxide (InGaZnO), zirconium indium zinc oxide (ZrInZnO), hafnium indium zinc oxide (HfInZnO), tin indium zinc oxide (SnInZnO), aluminum tin indium zinc oxide (AlSnInZnO), silicon indium zinc oxide (SiInZnO), zinc tin oxide (ZnSnO), aluminum zinc tin oxide (AlZnSnO), gallium zinc tin oxide (GaZnSnO), zirconium zinc tin oxide (ZrZnSnO), and indium gallium silicon oxide (InGaSiO).

Due to the first conductive layer 122 and the second conductive layer 153 including the oxide semiconductor material, resistance between the active pattern AP and the landing pad 120 and between the active pattern AP and the bit line 150 may be reduced. In some implementations, the first conductive layer 122 and the second conductive layer 153 may include a material having conductivity higher than that of the active pattern AP.

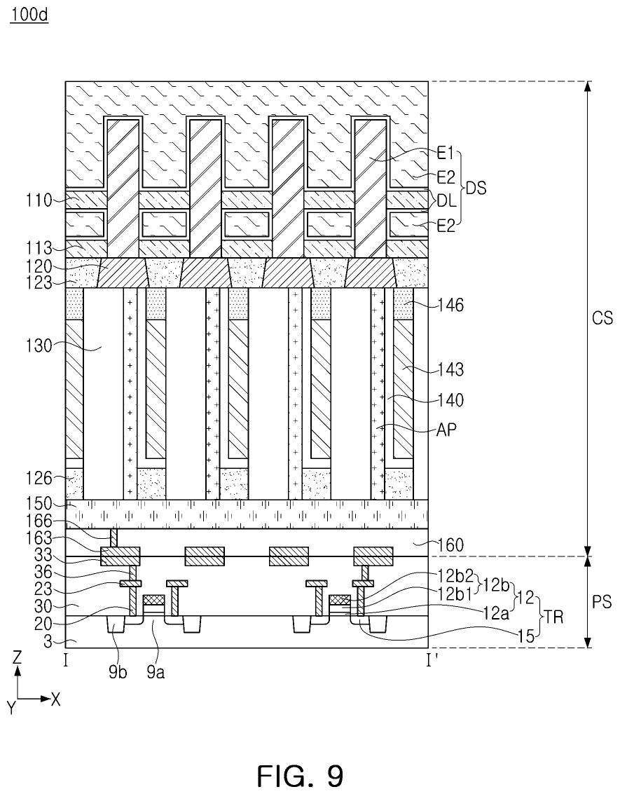

Referring to FIG. 9, a semiconductor device 100d may include a cell array structure CS and a peripheral circuit structure PS. In some implementations, the semiconductor device 100d may have a cell on peri (COP) structure in which the cell array structure CS is disposed on the peripheral circuit structure PS. For example, a lower surface of the active pattern AP may be in contact with the bit line 150, and an upper surface of the active pattern AP may be in contact with the landing pad 120. For example, a lower surface of the landing pad 120 may be in contact with the insulating structure 130, the gate dielectric layer 140, and the gate capping layer 146. An upper surface of the bit line 150 may be in contact with the insulating structure 130 and the insulating pattern 126.

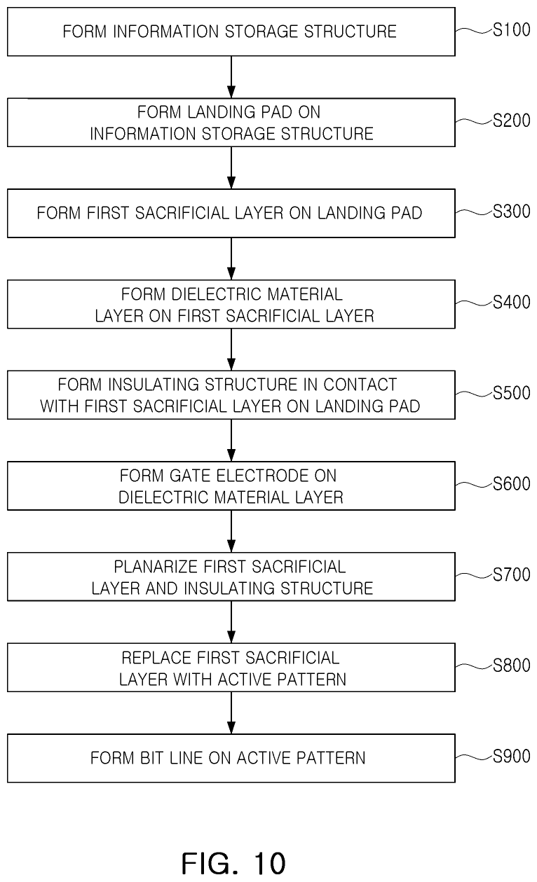

FIG. 10 is a flowchart of a method of manufacturing a semiconductor device according to some implementations.

Referring to FIG. 10, a method of manufacturing a semiconductor device may include forming a cell array structure and bonding the cell array structure to a peripheral circuit structure. The forming the cell array structure may include forming an information storage structure (S100), forming a landing pad on the information storage structure (S200), forming a first sacrificial layer on the landing pad (S300), forming a dielectric material layer on the first sacrificial layer (S400), forming an insulating structure in contact with the first sacrificial layer on the landing pad (S500), forming a gate electrode on the dielectric material layer (S600), planarizing the first sacrificial layer and the insulating structure (S700), replacing the first sacrificial layer with an active pattern (S800), and forming a bit line on the active pattern (S900).

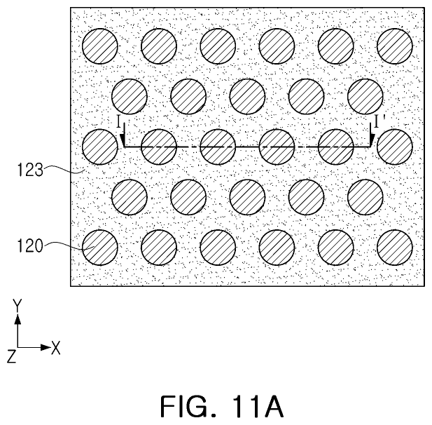

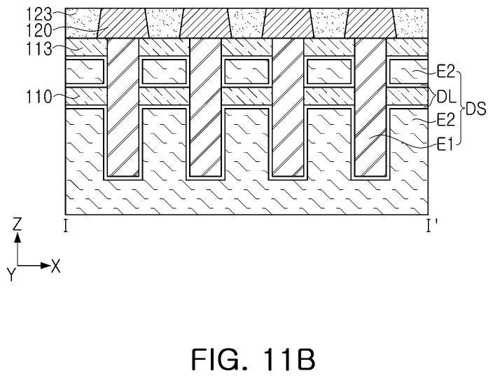

FIGS. 11A, 11B, 12A, 12B, 13A, 13B, 14A, 14B, 15, 16A, 16B, 17A, 17B are plan views and vertical cross-sectional views of sequential processes in a method of manufacturing a semiconductor device according to some implementations. FIGS. 11A, 12A, 13A, 14A, 16A, and 17A are plan views corresponding to FIG. 1. FIGS. 11B, 12B, 13B, 14B, 15, 16B, and 17B are vertical cross-sectional views corresponding to FIG. 2.

Referring to FIGS. 10, 11A, and 11B, an information storage structure DS may be formed (S100), and a landing pad 120 may be formed on the information storage structure DS (S200).

The information storage structure DS may include first electrodes E1, second electrodes E2 on the first electrodes E1, and a dielectric layer DL between the first electrodes E1 and the second electrodes E2. In some implementations, a lower supporter layer 110 and an upper supporter layer 113, disposed between the first electrodes E1, may further be provided.

The landing pad 120 may be formed on the information storage structure DS. For example, a conductive layer, covering an upper surface of the upper supporter layer 113 and upper surfaces of the first electrodes E1, may be formed on the information storage structure DS. A mask layer may be formed on the conductive layer, and the landing pads 120 may be formed by an anisotropic etching process using the mask layer as an etching mask. The landing pads 120 may be disposed on the corresponding first electrodes E1, respectively. After the landing pad 120 is formed, a pad insulating layer 123, covering a side surface of the landing pad 120, may be formed. An upper surface of the pad insulating layer 123 may be coplanar with an upper surface of the landing pad 120.

In some implementations, the landing pads 120 may be disposed in a honeycomb structure. For example, the landing pads 120 may be disposed at respective vertices of a hexagon and at the center of the hexagon.

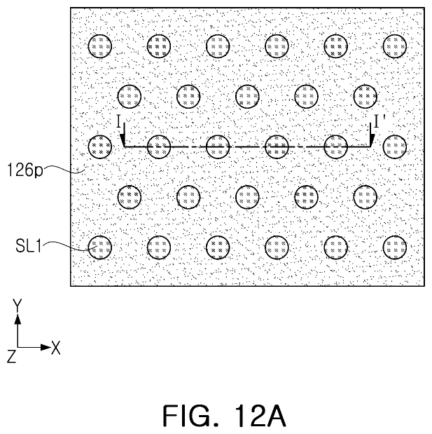

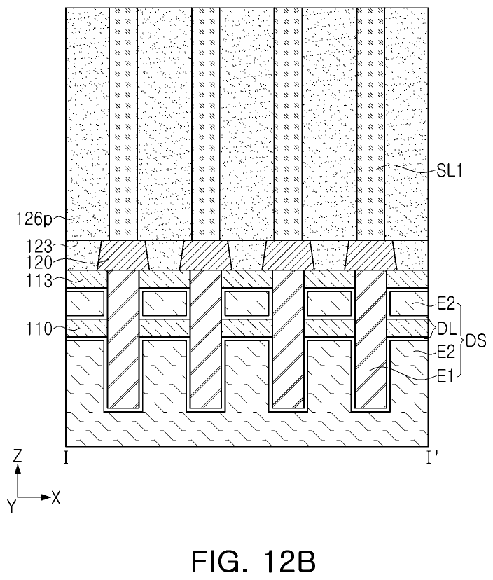

Referring to FIGS. 10, 12A, and 12B, a first sacrificial layer SL1 may be formed on the landing pad 120 (S300). After an insulating material layer 126p is formed to cover the landing pad 120 and the pad insulating layer 123, the first sacrificial layer SL1 may be formed in the insulating material layer 126p. The first sacrificial layers SL1 may be disposed on the corresponding landing pads 120, respectively. For example, the first sacrificial layers SL1 may be disposed in a honeycomb structure.

The insulating material layer 126p may include silicon oxide, silicon nitride, silicon oxynitride, a low-κ dielectric, or combinations thereof. For example, the insulating material layer 126p may include silicon nitride. The first sacrificial layer SL1 may include a material having an etch selectivity with respect to the insulating material layer 126p. For example, the first sacrificial layer SL1 may include polysilicon.

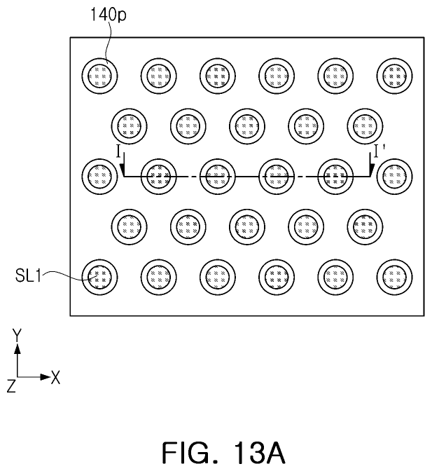

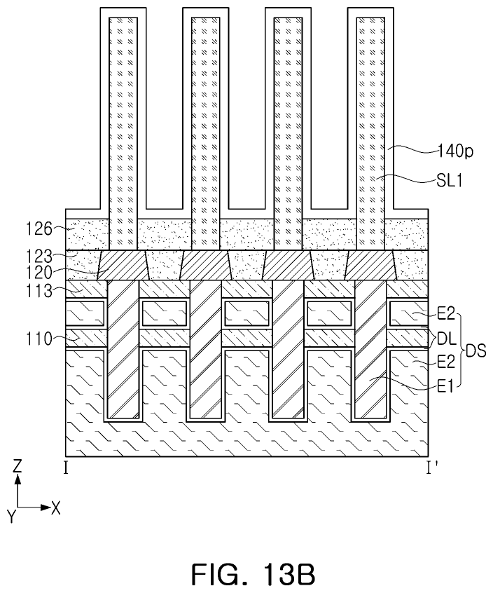

Referring to FIGS. 10, 13A, and 13B, a dielectric material layer 140p may be formed on the first sacrificial layer SL1 (S400). Before the dielectric material layer 140p is formed, the insulating material layer 126p may be selectively etched to form an insulating pattern 126. The insulating pattern 126 may cover a lower portion of a side surface of the first sacrificial layer SL1, and an upper portion of the side surface of the first sacrificial layer SL1 and an upper surface of the first sacrificial layer SL1 may be exposed. The dielectric material layer 140p may cover an upper surface of the insulating pattern 126, the upper portion of the side surface of the first sacrificial layer SL1, and the upper surface of the first sacrificial layer SL1.

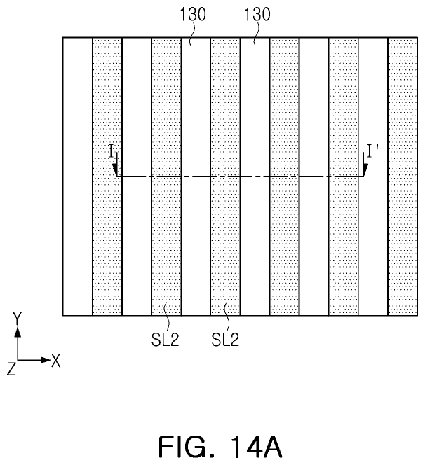

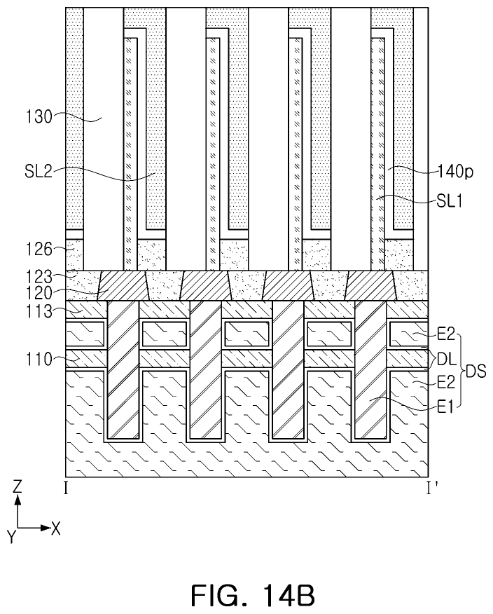

Referring to FIGS. 10, 14A, and 14B, an insulating structure 130 in contact with the first sacrificial layer SL1 may be formed on the landing pad 120 (S500). In some implementations, before the insulating structure 130 is formed, a second sacrificial layer SL2 may be formed to cover the dielectric material layer 140p. By an anisotropic etching process, trenches, exposing the insulating pattern 126, the first sacrificial layer SL1, the second sacrificial layer SL2, and the dielectric material layer 140p, may be formed. The insulating structure 130 may be formed by depositing an insulating material layer into the trenches. The insulating structure 130 may extend in a Y-direction, and may be spaced apart from each other in an X-direction. The insulating structure 130 may be in contact with the first sacrificial layer SL1, the second sacrificial layer SL2, and the dielectric material layer 140p. For example, in the anisotropic etching process, a portion of the first sacrificial layer SL1 and the dielectric material layer 140p may be etched.

The insulating structure 130 may include silicon oxide, silicon nitride, silicon oxynitride, a low-κ dielectric, or combinations thereof. For example, the insulating structure 130 may include silicon oxide.

The second sacrificial layers SL2 may extend in the Y-direction, and may be spaced apart from each other in the X-direction. For example, the second sacrificial layers SL2 may be alternately disposed with the insulating structures 130 in the X-direction. The second sacrificial layers SL2 may include a material having an etch selectivity with respect to the insulating structure 130 and the dielectric material layer 140p. For example, the second sacrificial layers SL2 may include silicon nitride.

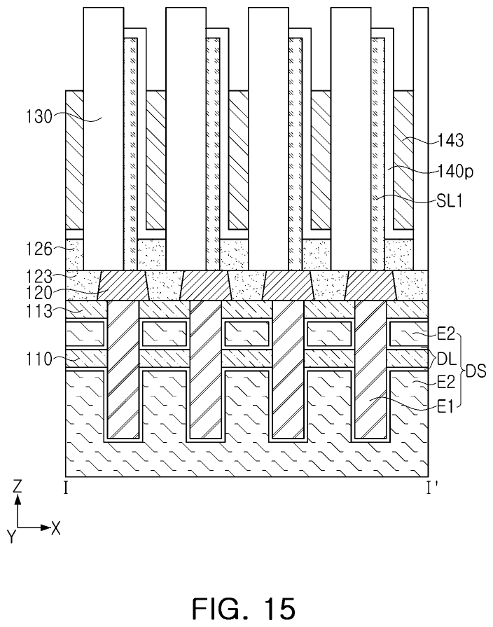

Referring to FIGS. 10 and 15, a gate electrode 143 may be formed on the dielectric material layer 140p (S600). First, the second sacrificial layers SL2 may be selectively removed. By removing the second sacrificial layers SL2, the insulating structures 130 and the dielectric material layer 140p may be exposed. A conductive material layer may be formed in a space from which the second sacrificial layers SL2 are removed, and the gate electrodes 143 may be formed on the dielectric material layer 140p by etching back the conductive material layer. The gate electrodes 143 may extend in the Y-direction, and may be spaced apart from each other in the X-direction. For example, the gate electrodes 143 may be alternately disposed with the insulating structures 130 in the X-direction.

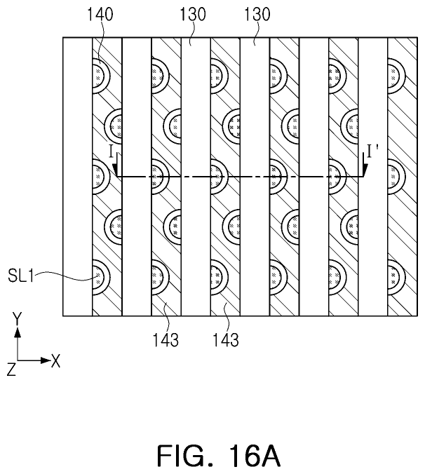

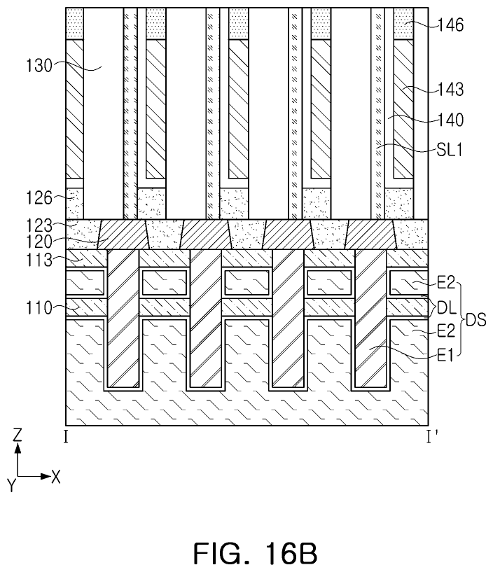

Referring to FIGS. 10, 16A, and 16B, the first sacrificial layer SL1 and the insulating structure 130 may be planarized (S700). In some implementations, before a planarization process is performed, an insulating material layer, covering the insulating structure 130, the dielectric material layer 140p, and the gate electrode 143, may be formed. The planarization process may be performed such that the first sacrificial layer SL1 and the insulating structure 130 are exposed. By the planarization process, the dielectric material layer 140p and the insulating material layer may be etched to form a gate dielectric layer 140 and a gate capping layer 146, respectively. After the planarization process, the insulating structure 130, the first sacrificial layer SL1, the gate dielectric layer 140, and the gate capping layer 146 may be coplanar with each other.

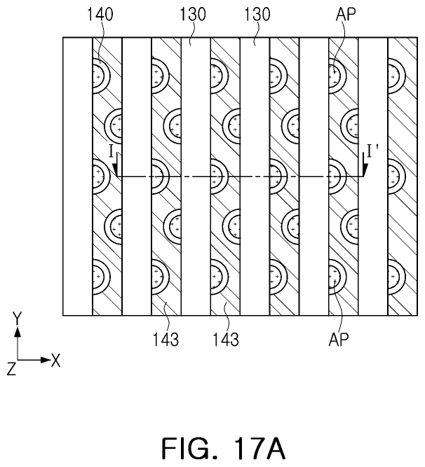

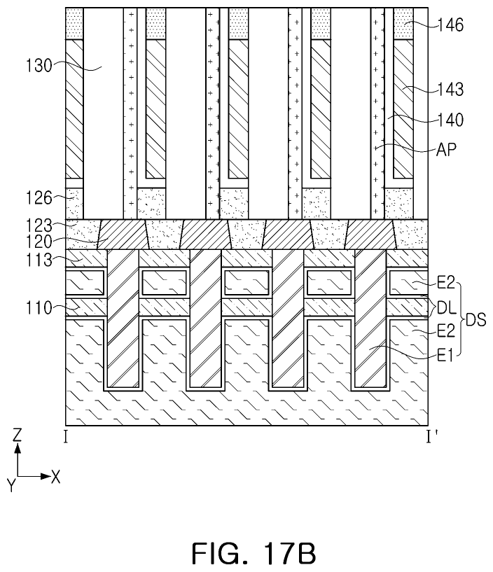

Referring to FIGS. 10, 17A, and 17B, the first sacrificial layer SL1 may be replaced with an active pattern AP (S800). For example, the first sacrificial layer SL1 may be selectively removed to form an opening exposing the insulating structure 130 and the gate dielectric layer 140. The active pattern AP may be formed in the opening and on the gate dielectric layer 140. The active patterns AP may be disposed on the corresponding landing pads 120, respectively. For example, the active patterns AP may be disposed in a honeycomb structure.

Referring to FIGS. 1, 2, and 10, a bit line 150 may be formed on the active pattern AP (S900). The bit lines 150 may extend in the X-direction, and may be spaced apart from each other in the Y-direction. A cell array structure CS may be formed by further forming a cell insulating layer 160, a first bonding pad 163, and a first contact 166 on the bit line 150. A semiconductor device 100 may be manufactured by bonding a peripheral circuit structure PS including circuit elements TR to the cell array structure CS. For example, a peripheral insulating layer 30 and a second bonding pad 33 of the peripheral circuit structure PS may be bonded to the cell insulating layer 160 and the first bonding pad 163, respectively.

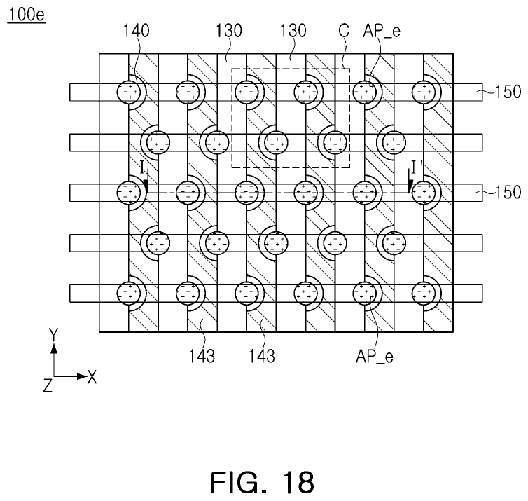

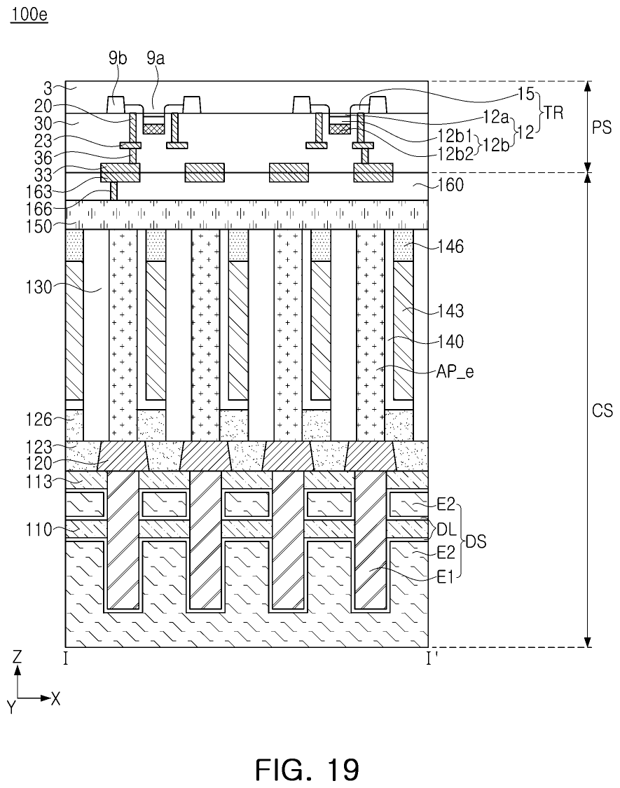

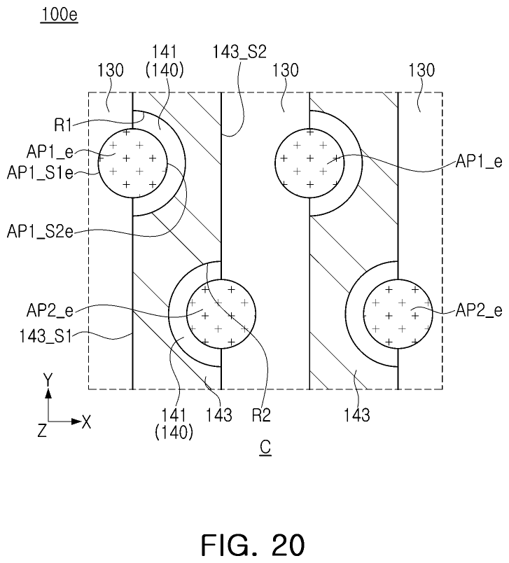

FIG. 18 is a plan view of a semiconductor device according to some implementations. FIG. 19 is a vertical cross-sectional view of the semiconductor device illustrated in FIG. 18, taken along line I-I′. FIG. 20 is a partially enlarged view of the semiconductor device illustrated in FIG. 18. FIG. 20 may correspond to region “c” of FIG. 13.

Referring to FIGS. 18 to 20, a semiconductor device 100e may include active patterns AP_e between landing pads 120 and bit lines 150. In some implementations, the active patterns AP_e may overlap a gate electrode 143 and an insulating structure 130 in a Y-direction.

A side surface of each of the active patterns AP_e may include a first portion AP_S1e in contact with the insulating structure 130 and a second portion AP_S2e in contact with the gate electrode 143. In some implementations, the first portion AP_S1e may overlap the insulating structure 130 in the Y-direction. For example, the first portion AP_S1e may not be in contact with the gate dielectric layer 140, and may not overlap the gate electrode 143 in the Y-direction. It illustrated that the first portion AP_S1e and the second portion AP_S2e have the same area and shape, but the present disclosure is not limited thereto.

A first side surface 143_S1 of the gate electrode 143 may include first recesses R1 spaced apart from each other in the Y-direction, and a second side surface 143_S2 of the gate electrode 143 may include second recesses R2 spaced apart from each other in the Y-direction. The active patterns AP_e may include first active patterns AP_1e overlapping the first recesses R1 in an X-direction, and second active patterns AP_1e overlapping the second recesses R2 in the X-direction. The first active patterns AP_1e and the second active patterns AP_1e may be disposed to be offset from each other in the X-direction, and may be alternately disposed in the Y-direction.

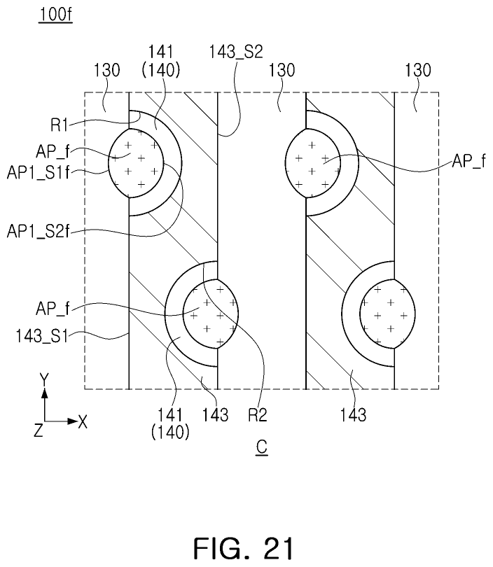

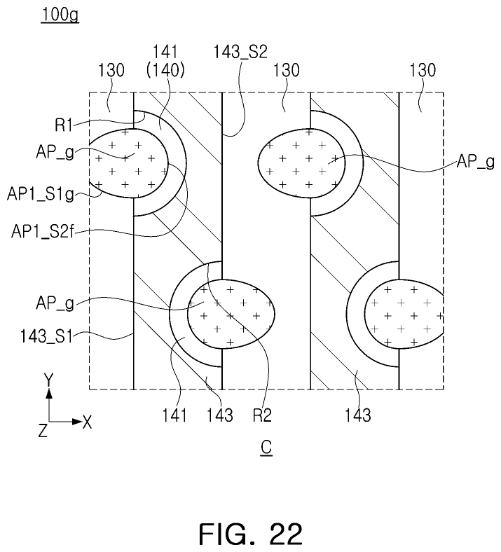

FIGS. 21 and 22 are plan views of semiconductor devices according to some implementations.

Referring to FIG. 21, a semiconductor device 100f may include active patterns AP_f between landing pads 120 and bit lines 150. In some implementations, the active patterns AP_f may overlap a gate electrode 143 and an insulating structure 130 in a Y-direction.

A side surface of each of the active patterns AP_f may include a first portion AP_S1f in contact with the insulating structure 130, and a second portion AP_S2f in contact with the gate electrode 143. In some implementations, the first portion AP_S1f may have a shape different from that of the second portion AP_S2f. For example, a radius of curvature of the first portion AP_S1f may be different from a radius of curvature of the second portion AP_S2f. A size of a portion of the active pattern AP_f overlapping the insulating structure 130 may be different from a size of a portion of the active pattern AP_f overlapping the gate electrode 143. For example, the size of the portion of the active pattern AP_f overlapping the insulating structure 130 may be smaller than the size of the portion of the active pattern AP_f overlapping the gate electrode 143.

Referring to FIG. 22, a semiconductor device 100g may include active patterns AP_g between landing pads 120 and bit lines 150. In some implementations, the active patterns AP_g may overlap a gate electrode 143 and an insulating structure 130 in a Y-direction.

A side surface of each of the active patterns AP_g may include a first portion AP_S1g in contact with the insulating structure 130 and a second portion AP_S2g in contact with the gate electrode 143. In some implementations, the first portion AP_S1g may have a different shape from the second portion AP_S2g. For example, a radius of curvature of the first portion AP_S1g may be different from a radius of curvature of the second portion AP_S2g. A size of a region of the active pattern AP_g overlapping the insulating structure 130 may be different from a size of a region overlapping the gate electrode 143. For example, the size of the region where the active pattern AP_g overlaps the insulating structure 130 may be greater than the size of the region in which the active pattern AP_g overlaps the gate electrode 143.

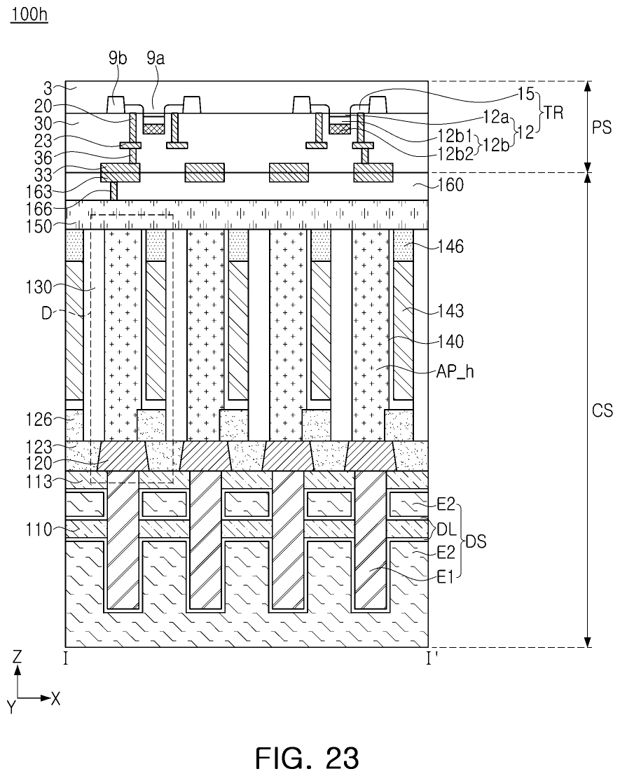

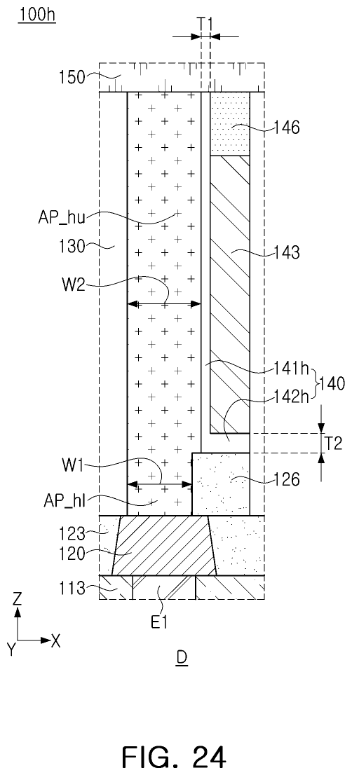

FIG. 23 is a vertical cross-sectional view of a semiconductor device according to some implementations. FIG. 24 is a partially enlarged view of the semiconductor device illustrated in FIG. 23.

Referring to FIGS. 23 and 24, a semiconductor device 100h may include active patterns AP_h between landing pads 120 and bit lines 150. In some implementations, the active pattern AP_h may include a lower portion AP_hl and an upper portion AP_hu on the lower portion AP_hl. For example, a portion of the active pattern AP_h overlapping an insulating pattern 126 in a horizontal direction may be referred to as the lower portion AP_hl.

In some implementations, a horizontal width of the upper portion AP_hu may be greater than a horizontal width of the lower portion AP_hl. For example, the lower portion AP_hl may have a first width W1 in an X-direction, and the upper portion AP_hu may have a second width W2 in the X-direction, greater than the first width W1. In some implementations, the lower portion AP_hl may be in contact with a side surface of the insulating pattern 126, and the upper portion AP_hu may be in contact with an upper surface of the insulating pattern 126. For example, the upper portion AP_hu may overlap the insulating pattern 126 in a vertical direction.

A gate dielectric layer 140 may include a vertical portion 141h and a horizontal portion 142h. In some implementations, the vertical portion 141h may have a thickness different from that of the horizontal portion 142h. For example, the vertical portion 141h may have a first thickness T1, and the horizontal portion 142h may have a second thickness T2, greater than the first thickness T1.

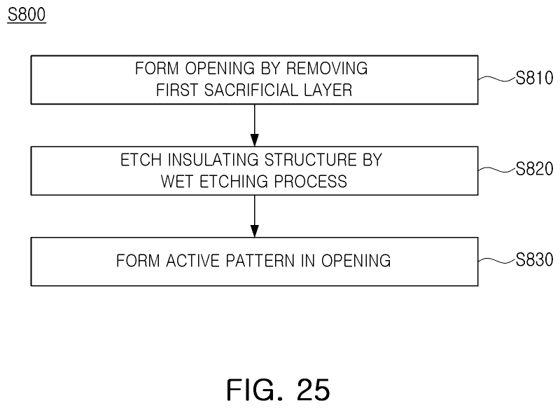

FIG. 25 is a flowchart of a method of manufacturing a semiconductor device according to some implementations.

Referring to FIG. 25, the replacing the first sacrificial layer with the active pattern (S800) may include forming an opening by removing the first sacrificial layer (S810), etching the insulating structure by a wet etching process (S820), and forming the active pattern in the opening (S830).

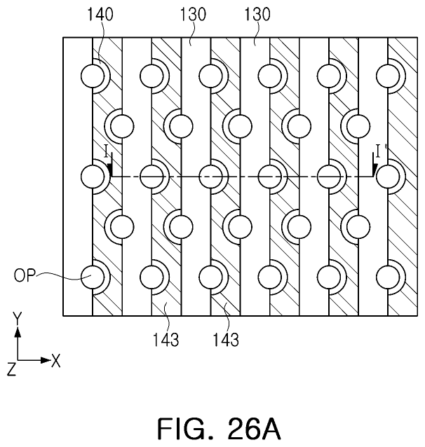

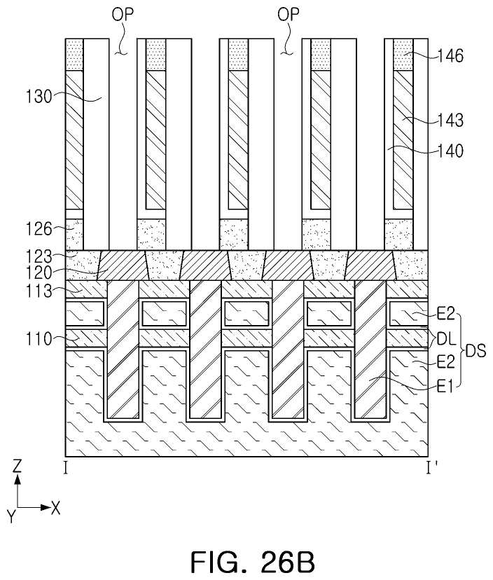

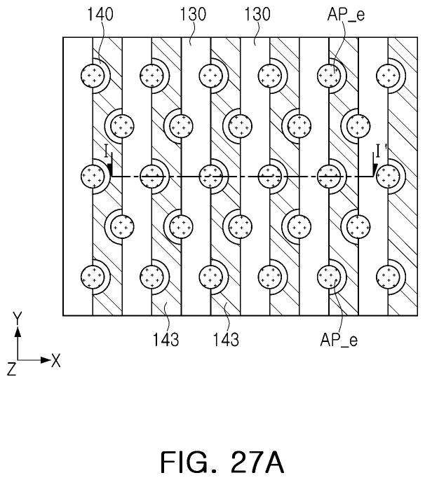

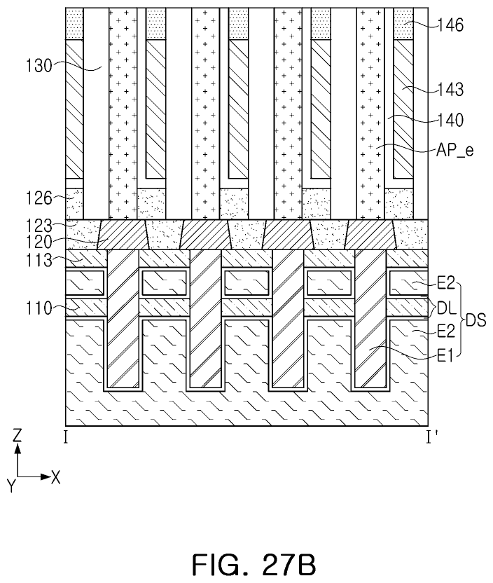

FIGS. 26A, 26B, 27A, 27B are plan views and vertical cross-sectional views of sequential processes in a method of manufacturing a semiconductor device according to some implementations. FIGS. 26A and 27A are plan views corresponding to FIG. 18. FIGS. 26B and 27B are vertical cross-sectional views corresponding to FIG. 19.

Referring to FIGS. 25, 26A, and 26B, after the first sacrificial layer SL1 and the insulating structure 130 are planarized (S700), the first sacrificial layer SL1 may be removed, and an opening OP may be formed in a space from which the first sacrificial layer SL1 is removed (S810). The opening OP may expose the insulating structure 130 and the gate dielectric layer 140.

After the opening OP is formed (S810), the insulating structure 130 may be etched by a wet etching process (S820). The insulating structure 130 may be partially etched by the wet etching process, and the opening OP may be expanded. For example, a side surface of the insulating structure 130 may include recesses, and the side surface of the insulating structure 130 exposed by the opening OP may include a curved surface.

Referring to FIGS. 25, 26A, and 26B, an active pattern AP_e may be formed in the opening OP (S830). As described with reference to FIG. 20, a portion of the active pattern AP_e may overlap the insulating structure 130 in a Y-direction.

Subsequently, as described with reference to FIGS. 2 and 10, a bit line 150 may be formed on the active pattern AP_e (S900), and a cell array structure CS may be formed by further forming a cell insulating layer 160, a first bonding pad 163, and a first contact 166 on the bit line 150. The semiconductor device 100e may be manufactured by bonding a peripheral circuit structure PS including circuit elements TR to the cell array structure CS.

According to another aspect of the present disclosure, there is provided a method of manufacturing a semiconductor device, the method including forming a landing pad, forming a first sacrificial layer on the landing pad, forming a dielectric material layer on the first sacrificial layer, forming, on the landing pad, an insulating structure in contact with the first sacrificial layer, the insulating structure extending in a first horizontal direction, forming a gate electrode on the dielectric material layer, planarizing the first sacrificial layer and the insulating structure, replacing the first sacrificial layer with an active pattern, and forming a bit line on the active pattern.

The method may further include forming an information storage structure including a first electrode, a dielectric layer covering the first electrode, and a second electrode on the dielectric layer, before forming the landing pads. The landing pad may be in contact with the first electrode.

The method may further include forming a second sacrificial layer covering the dielectric material layer, before forming the insulating structure. The insulating structure may pass through the second sacrificial layer, and may be in contact with the landing pad.

The method may further include exposing the dielectric material layer and the insulating structure by removing the second sacrificial layer, before forming the gate electrode.

The method may further include forming a gate capping layer covering the gate electrode, after forming the gate electrode.

The replacing the first sacrificial layer with the active pattern may include forming an opening exposing the insulating structure by removing the first sacrificial layer, and forming the active pattern in the opening.

The method may further include etching the insulating structure by a wet etching process, after forming the opening.

A gate dielectric layer may be formed by etching the dielectric material layer, when planarizing the insulating structure. The gate dielectric layer may cover a lower surface and a side surface of the gate electrode.

The gate electrode may include a first side surface including first recesses, and a second side surface opposite to the first side surface, the second side surface including second recesses. The active pattern may include first active patterns overlapping the first recesses in a second horizontal direction, intersecting the first horizontal direction, and second active patterns overlapping the second recesses in the second horizontal direction. The first active patterns and the second active patterns may be alternately disposed in the first horizontal direction.

The first active patterns and the second active patterns may be disposed to be offset from each other in the second horizontal direction.

According to some implementations of the present disclosure, active patterns may be disposed in a honeycomb structure, thereby implementing a semiconductor device having a smaller size, and achieving integration of the semiconductor device.

While some implementations have been shown and described above, it will be apparent to those skilled in the art that modifications and variations could be made without departing from the scope of the present disclosure as defined by the appended claims.

As used herein, the term “at least one of” can refer to and encompass any and all possible combinations of one or more of the associated listed terms. For example, the term “at least one of A, B, or C” means that (i) at least one of A, (ii) at least one of B, (iii) at least one of C, (iv) at least one of A and at least one of B, (v) at least one of B and at least one of C, (vi) at least one of A and at least one of C, or (vi) at least one of A, at least one of B and at least one of C are possible, where A, B and C may be singular or plural.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A semiconductor device comprising:
active patterns extending in a vertical direction, wherein the active patterns are spaced apart from each other in a first horizontal direction;
landing pads and bit lines in contact with the active patterns, wherein the landing pads and the bit lines are spaced apart from each other in the vertical direction with the active patterns interposed between the landing pads and the bit lines, wherein the bit lines extend in a second horizontal direction that intersects the first horizontal direction;
a gate electrode surrounding at least a portion of the active patterns, wherein the gate electrode extends in the first horizontal direction; and
a gate dielectric layer between the active patterns and the gate electrode, wherein the gate dielectric layer at least partially covers side surfaces of the active patterns,
wherein the gate electrode includes a first side surface that defines first recesses and a second side surface that is opposite to the first side surface and defines second recesses,
wherein the active patterns include first active patterns overlapping with the first recesses in the second horizontal direction, and second active patterns overlapping with the second recesses in the second horizontal direction, and
wherein the first active patterns and the second active patterns are alternately arranged in the first horizontal direction.

2. The semiconductor device of claim 1, wherein the first active patterns and the second active patterns are offset from each other in the second horizontal direction.

3. The semiconductor device of claim 1, wherein the first active patterns are coplanar with the first side surface of the gate electrode, and
wherein the second active patterns are coplanar with the second side surface of the gate electrode.

4. The semiconductor device of claim 1, wherein the gate dielectric layer includes:
a horizontal portion at least partially covering a lower surface of the gate electrode, wherein the horizontal portion extends in the first horizontal direction, and
vertical portions between the active patterns and the gate electrode, wherein the vertical portions extend in the vertical direction from the horizontal portion.

5. The semiconductor device of claim 4, wherein the vertical portions are spaced apart from each other in the first horizontal direction.

6. The semiconductor device of claim 4, wherein the vertical portions are coplanar with upper surfaces of the active patterns, and
wherein the horizontal portion is higher, with respect to a substrate, than lower surfaces of the active patterns.

7. The semiconductor device of claim 4, wherein the vertical portions include:
first vertical portions between the first active patterns and the gate electrode, wherein the first vertical portions at least partially cover the first recesses, and
second vertical portions between the second active patterns and the gate electrode, wherein the second vertical portions at least partially cover the second recesses, and
wherein the first vertical portions and the second vertical portions are alternately arranged in the first horizontal direction.

8. The semiconductor device of claim 7, wherein the first vertical portions are coplanar with the first side surface of the gate electrode, and
wherein the second vertical portions are coplanar with the second side surface of the gate electrode.

9. The semiconductor device of claim 4, comprising:
an insulating pattern between the landing pads and the gate electrode,
wherein an upper surface of the insulating pattern is in contact with the horizontal portion of the gate dielectric layer.

10. The semiconductor device of claim 1, comprising:
a liner layer in contact with side surfaces and a lower surface of the gate electrode.

11. The semiconductor device of claim 1, wherein the active patterns at least partially pass through the landing pads.

12. The semiconductor device of claim 1, comprising:
first conductive layers between the active patterns and the landing pads,
wherein the first conductive layers are spaced apart from each other in the first horizontal direction and in the second horizontal direction.

13. The semiconductor device of claim 1, comprising:
second conductive layers between the active patterns and the bit lines,
wherein the second conductive layers extend in the second horizontal direction.

14. The semiconductor device of claim 1, wherein each of the side surfaces of the active patterns includes:
a first portion is offset from the gate electrode in the first horizontal direction, and
a second portion overlapping with the gate electrode in the first horizontal direction.

15. The semiconductor device of claim 14, wherein the first portions of the side surfaces of the active patterns are different in shape from each of the second portions of the side surfaces of the active patterns.

16. A semiconductor device comprising:
active patterns extending in a vertical direction, wherein the active patterns are spaced apart from each other in a first horizontal direction;
landing pads and bit lines in contact with the active patterns, wherein the landing pads and the bit lines are spaced apart from each other in the vertical direction with the active patterns interposed between the landing pads and the bit lines, wherein the bit lines extend in a second horizontal direction, intersecting the first horizontal direction;
a gate electrode surrounding at least a portion of the active patterns, wherein the gate electrode extends in the first horizontal direction, and wherein the gate electrode includes a first side surface that defines first recesses, and a second side surface that is opposite to the first side surface and defines second recesses;
a first insulating structure in contact with the first side surface of the gate electrode, wherein the first insulating structure extends in the first horizontal direction; and
a second insulating structure in contact with the second side surface of the gate electrode, wherein the second insulating structure extends in the first horizontal direction,
wherein the active patterns include first active patterns overlapping with the first recesses in the second horizontal direction, and second active patterns overlapping with the second recesses in the second horizontal direction,
wherein the first active patterns are in contact with the first insulating structure,
wherein the second active patterns are in contact with the second insulating structure, and
wherein the first active patterns and the second active patterns are alternately arranged in the first horizontal direction.

17. The semiconductor device of claim 16, wherein
the first active patterns are coplanar with a side surface of the first insulating structure, and
wherein the second active patterns are coplanar with a side surface of the second insulating structure.

18. The semiconductor device of claim 16, wherein a portion of the first active patterns overlaps with the first insulating structure in the first horizontal direction.

19. The semiconductor device of claim 16, wherein a size of each of the portions of the first active patterns overlapping with the first insulating structure in the first horizontal direction is different from a size of each of the portions of the first active patterns overlapping with the gate electrode in the first horizontal direction.

20. A semiconductor device comprising:
a cell array structure; and
a peripheral circuit structure bonded to the cell array structure,
wherein the cell array structure includes:
active patterns extending in a vertical direction, wherein the active patterns are spaced apart from each other in a first horizontal direction;
landing pads and bit lines in contact with the active patterns, wherein the landing pads and the bit lines are spaced apart from each other in the vertical direction with the active patterns interposed therebetween, wherein the bit lines extends in a second horizontal direction that intersects the first horizontal direction;
a gate electrode surrounding at least a portion of the active patterns, wherein the gate electrode extends in the first horizontal direction, wherein the gate electrode includes a first side surface that defines first recesses and a second side surface that is opposite to the first side surface and defines second recesses; and
an information storage structure on the landing pads,
wherein the peripheral circuit structure includes a circuit element on a substrate, the circuit element electrically connected to the bit line,
wherein the active patterns include first active patterns overlapping with the first recesses in the second horizontal direction, and second active patterns overlapping with the second recesses in the second horizontal direction, and
wherein the first active patterns and the second active patterns are alternately arranged in the first horizontal direction.
